(19) United States
(12) Patent Application Publication
(10) Pub. No.: US 2004/0013143 A1
(43) Pub. Date: Jan. 22, 2004

(54) Confinement layer of buried heterostructure semiconductor laser

(76) Inventors: Anthony J. Springthorpe, Richmond (CA); Paul J. Paddon, Vancouver (CA); Grzegorz J. Pakulski, Woodlawn (CA)

Correspondence Address: LAHIVE & COCKFIELD, 28 STATE STREET, BOSTON, MA, 02109, US

(21) Appl. No.: 10/014,807

(22) Filed: Dec. 14, 2001

(30) Foreign Application Priority Data
Dec. 15, 2000 (CA) 2,328,641

(51) Int. Cl. H01S 5/00

(52) U.S. Cl. 372/45; 372/46

(57) ABSTRACT

A laser device having an improved electrical confinement has been disclosed The confinement of laser is composed of a material of AlInAs doped with oxygen. Also, it may further comprise aluminum oxide (Al₂O₃), which may take the form of an aluminum oxide (Al₂O₃) layer formed along the interface between the confinement and neighboring components of the device.

### FIELD OF THE INVENTION

The present invention relates to an electrical confinement of optical semiconductor devices, and more particularly relates to a new application of materials to the electrical confining means in the conventional buried heterosturcture semiconductor laser.

### BACKGROUND OF THE INVENTION

Conventionally, the buried heterostucture semiconductor laser (hereafter, referred to as a “BH laser”) may take various type of architecture according to its applications. In FIG. 1 is shown a standard structure of an InP-based BH laser 20, which comprises a substrate 21, on which a buffer layer 22, an active region 23, a confinement region 25, a cladding layer 24, and a contact layer 26 are successively deposited or regrown. The substrate 21 and the buffer layer 22 are composed of an n-type InP, while the cladding layer 24 and the contact layer 26 are composed of a p-type InP, and vice versa, in order to form a pn junction. Usually, zinc is utilized as an acceptor impurity to provide the cladding layer 24 and the contact layer 26 with a p-type polarity.

As illustrated in FIG. 1, the active region 23 takes the form of a mesa ridge together with the cladding layer 24 and part of the buffer layer 22. The mesa ridge structure including the active region 23 is typically surrounded by the confinement region 25 so that, in the operation of the laser, the electric current flow converges into the active region 23 due to the high resistivity of the confinement region 25, resulting in laser devices with reduced threshold, high quantum efficiency, and improved high frequency performance. Any current leakage from the active region 23 results in a lower quantum efficiency and a curved, thus non-linear, power-current-characteristic. Therefore, it is desirable that the leakage currents be kept as small as possible.

Many attempts have been made in order to improve these characteristics of the confinement region. One of these is that, for the InP-based laser structures, the confinement layer or region is either a sequence of alternating p- and n-type layers of InP, or a resistive layer of Fe-doped InP. With the conventional BH laser adopting the Fe-doped InP as the confinement layer material, during the re-growth of the Fe-doped InP, the Fe-doped InP material close to the mesa active region is likely to be converted to a conductive p-type layer by in-diffusion of zinc from the p-InP of the mesa ridge to the confinement layer. Usually, zinc is used as an acceptor impurity to the p-InP. Out-diffusion of iron from the Fe-doped InP confinement layer also occurs, which promotes the zinc diffusion process. This conductive layer, therefore, provides a current shorting path, so that not all of the applied current passes usefully through the laser.

The zinc diffusion phenomenon is especially troublesome around the Zn-doped mesa of the BH active layer and the Fe-doped confinement layers as shown in FIG. 1. The phenomenon occurs mainly during growth (or overgrowth) at elevated temperatures. The presence of Zn in the confinement region creates current leakage paths, manifesting itself in high laser threshold and low efficiency. The semi-insulating nature of the Fe-doped InP is due to a deep acceptor. This deep acceptor compensates the ususal n-type background, so that for a bulk layer the Fermi level is near the centre of the bandgap. This means that the thermal carrier concentration is small, and the resistance is high. This high resistance of the Fe-doped INP layer is intended to funnel the injected carriers through the active region. Under the applied bias, however, extra carriers can be injected into the semi-insulating material. Because the thermal carrier concentrations are so low, only a small applied bias is needed to substantially increase the carrier concentration. The added carriers result in a decrease in resistance of the layer. In addition, high background donor or acceptor concentrations may also render the Fe-doped InP layer conductive.

Although there are elaborate schemes to reduce this effect (the use of silicon fences, for example to preferentially soak up the diffusion atoms), they are far from satisfactory, and the resulting devices have less than optimal performance.

Accordingly, it is an object of the present invention to provide an improved BH laser architecture which comprises an improved and more effective electrical confining means.

It is another object of the present invention to provide an improved and more effective electrical confining means which can be used for optoelectronic semiconductor devices.

### SUMMARY OF THE INVENTION

In accordance with the present invention, there is provided a laser device having an improved electrical confining characteristics, which includes the use of AlInAs doped with oxygen in the confinement region. The confinement region serves to confine the flow of electrical current to the active region of the laser and also serves to guide a radiation emitted from the active region. The confinement region of the invention may be formed by using a low temperature MOCVD (Metal-organic Chemical Vapor Deposition) or a digital alloy technique.

According to one of the features of the invention, the confinement region may further comprises aluminum oxide (Al₂O₃), which may take the form of an aluminum oxide (Al₂O₃) layer formed along the interface between the confinement region and its neighboring components including the active region. The aluminum oxide (Al₂O₃) layer may be formed by applying a heat-treatment in a wet nitrogen environment.

Preferably, the laser device of the invention may be an InP-based device which comprises a lattice-matched Al_{0.48}In_{0.52}As doped with oxygen as the confinement region. Also, the confinement region may further comprises aluminum oxide (Al₂O₃), which may take the form of an aluminum oxide (Al₂O₃) layer formed along the interface between the confinement and its neighboring components including the active region The aluminum oxide (Al₂O₃) layer, as noted above, may be formed by applying a heat-treatment in wet nitrogen environment.

The present invention may also provide for the use of AlInAs doped with oxygen as an electrical confining means for various optical semiconductor devices including InP-based devices. The AlInAs may also further comprise aluminum oxide (Al₂O₃), which may take the form of a layer which is formed along an interface between the electrical confining means and other components of the optical semiconductor device.

The optical semiconductor devices referred to above may include an InP-based semiconductor laser device, of which electrical confining means may comprise an InP lattice-matched Al_{0.48}In_{0.52}As doped with oxygen to the InP materials. Also, the lattice-matched Al_{0.48}In_{0.52}As doped with oxygen may further comprise aluminum oxide (Al₂O₃), which may take the form of a layer which is formed along an interface between the electrical confining means and other components of the InP-based semiconductor laser devices.

A further understanding of the other features, aspects, and advantages of the present invention will be realized by reference to the following description, appended claims, and accompanying drawings.

### BRIEF DESCRIPTION OF THE DRAWINGS

The embodiments of the invention will now be described with reference to the accompanying drawings, in which:

FIG. 1 is a schematic representation of the convention BH semiconductor laser, using a Fe-doped InP material as the confinement layer;

FIG. 2 is an illustration of the present invention, using an AlInAs material as the confinement region; and

FIG. 2A is another illustration of the present invention, showing a use of AlInAs material as part of the confinement region.

### DETAILED DISCLOSURE OF THE PREFERRED EMBODIMENT(S)

A basic concept of the present invention is that an AlInAs material doped with oxygen is used as the electrical confining means in the conventional semiconductor laser devices including a buried heterostructure (BH) semiconductor laser, furthermore in the optoeletronic semiconductor devices which needs electrical confining or blocking.

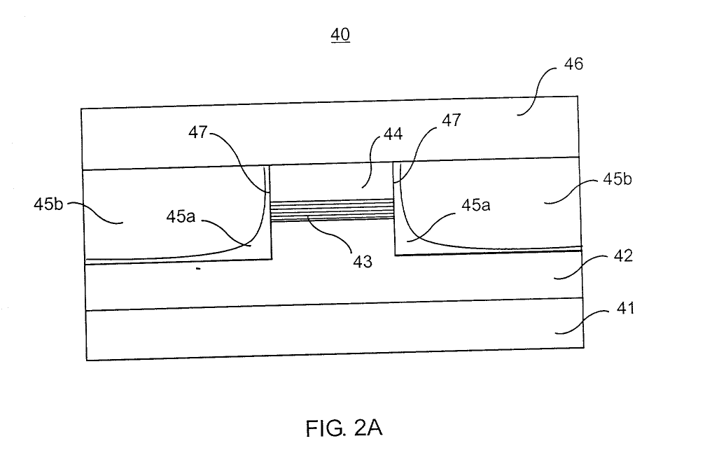

FIG. 2 depicts an embodiment of an InP-based BH semiconductor laser of the present invention where the AlInAs doped with oxygen is utilized for the confinement region of the laser. Throughout the description, an InP-based BH semiconductor laser is utilized for the purpose of explanation of the gist of the present invention, but the concept of the invention may be applied to various types of lasers to achieve an effective confinement or blocking of electric current.

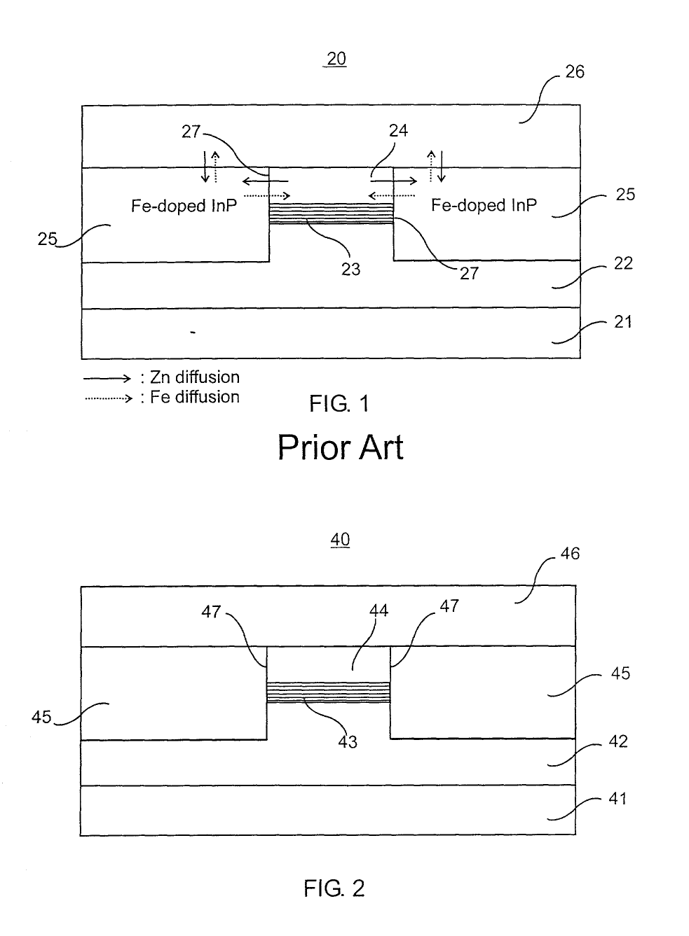

The fundamental structure of FIG. 2 is identical to the conventional BH semiconductor lasers shown in FIG. 1, except for using an AlInAs material doped with oxygen as the confinement layer (or region) of the laser. As illustrated in FIG. 2, the BH semiconductor laser 40 of the invention comprises a substrate 41, on which a buffer layer 42, an active region 43, a confinement region 45, a cladding layer 44, and a contact layer 46 are successively deposited or regrown. As will be understood by those skilled in the art, the substrate 41 and the buffer layer 42 should have an opposite polarity to the cladding layer 44 and the burying region 46 in order to form a pn junction and the active region 43 may comprise InGaAsP, Quantum Well structure, Mixed-Quantum Well, or various combinations thereof, etc. Also, a mesa ridge including the active region 43 is typically delineated in a lateral direction by surrounding the mesa strip with the confinement region 45 so that, in the operation of the laser, the electric current flow converges into the active region 43.

In accordance with the features of the invention, the confinement region 45 of the laser comprises an AlInAs doped with oxygen, which may be regrown around the active region 43 after selective etching to build a mesa structure. The regrowth process will be described below in details The AlInAs doped with oxygen can be lattice-matched to InP material, and has a higher electrical bandgap than those of InP and other components of the laser. For example, a lattice-matched AlInAs alloy has ˜1.5 eV bandgap. Also, the AlInAs doped with oxygen provides very high resistivity so that the confinement or blocking of the current flow can be effectively achieved to increase the quantum efficiency in the active region 43. Since the oxygen atoms are far less mobile than the iron atoms of Fe-doped InP confinement as in the prior art, the zinc diffusion problem can be avoided.

The regrown layer or region, i.e., the confinement region 45 in FIG. 2, can be achieved by low temperature growth of AlInAs by MOCVD. The general idea of the regrowth process is well-known in the semiconductor industries. In the regrowth process of oxygen-compensated material AlInAs in this embodiment of the InP-based BH semiconductor laser, the basic reaction is that of an organometallic gallium containing compound such as tri-ethyl gallium with an aluminium containing compound such as tri-ethyl aluminium, in the presence of arsine, or an organometallic arsenic containing compound such as tri-methyl arsenic in a carrier gas of hydrogen. The compounds thermally decompose on the substrate surface to form the AlInAs. The amount of the precursors should be controlled in the right proportions to ensure that the lattice matched Al_{0.48}In_{0.52}As composition is deposited. Typically, the reaction temperature is controlled to above 700° C. to avoid oxygen incorporation. For the application of the invention, it should be preserved at approximately 500° C. Since the reactions rely on the thermal decomposition of the precursors, lower temperatures than 500° C. do not work. If AlInAs is not grown by MOCVD at high temperatures (>650° C.), then it is generally highly resistive. The resistance may be due to the incorporation of oxygen, which introduces mid-gap trapping sites to the atomic structure. The oxygen can be avoided by going to specially prepared aluminum-containing organometallic precursors However, if run of the mill precursors are used, then there will be sufficient oxygen present to ensure that the AlInAs is grown with oxygen, and the resulting layer will be highly resistive. Oxygen may also be deliberately added as a doping gas, for example, in an amount of approximately 1×10¹⁹/cm³ to the epitaxial layer.

Alternatively, the confinement region of AlInAs may be provided in the semiconductor laser by using a digital alloy technique, in which AlAs and InAs layers are alternatively grown in the correct stoichiomety. In this case, the subsequent oxidation process may be more favourable, which will be described hereafter in more detail.

FIG. 2A illustrated another embodiment of the invention, in which the confinement region comprises a thin layer of AlInAs doped with oxygen 45a provided along the sidewalls of the mesa ridge including the active region 43. The thickness of the thin layer of oxygen-doped AlInAs may be for example 100 nm so that it is sufficient to eliminate any problems with the subsequent overgrowth of Fe-InP layer 45b.

Preferably, the confinement region of AlInAs doped with oxygen of the invention may further include aluminum oxide. More preferably, the aluminum oxide may take the form of an aluminum oxide (Al₂O₃) layer formed along the interface 47 between the oxygen-doped AlInAs region and its neighbouring components, such as the active region 43, the cladding layer 44, and even the contact layer 46 and the buffer layer 42 in FIGS. 2 and 2A. The aluminum oxide layer may be provided by oxidizing the regrown oxygen-doped AlInAs layer by applying a heat-treatment in a wet nitrogen environment. Therefore, the confinement region 45 and 45a of the invention may have a much higher resistance so that more effective confinement of current may be achieved It is preferable that the lateral oxidation of the oxygen-doped AlInAs layer be carried out after the final overgrowth and wide ridge trenching, but before the metallisation step in the manufacturing of the laser device.

The wet nitrogen heat treatment is a well-known technology, which will be briefly described below. The thermal oxidation of Al-containing semiconductors (for example, AlGaAs, AlInAs, AlInGaP) in a wet nitrogen atmosphere at elevated temperatures (350° C.-500° C.) was found to form a phase of Al₁O₃ which is mechanically stable, has a low refractive index and has reduced thickness with respect to the unconverted semiconductor layer. More detailed information is disclosed in the following: J. M. Dallesasse et al. “Hydrolyzation oxidation of AlGaAs-AlAs-GaAs Quantum well heterostructures,” Appl. Phys. Lett., vol. 57, p2844, 1990. The oxidation process is well-controlled, repeatable and commercially robust, and has found numerous applications in the field of optoelectronics, which is disclosed in K. D. Choquette et al. “Advances in selective wet oxidation of AlGaAs alloys,” IEEE J. Select. Top. Quant. Elec. vol. 3, p916, 1997.

The oxidation rate is found to depend logarithmically on the Al concentration, with materials containing the high Al-concentrations oxidizing the fastest. For MOCVD grown Al_{0.48}In_{0.52}As lattice matched to InP, the lateral oxidation rate at 520° C. is approximately 0.55 μm/hr, see P. Petit P. Legat et al. “Controlled steam oxidation of AlInAs for microelectronics and optoelectronics applications,” J. Elec. Mat., vol. 26, No 32, 1997. However, using a digital alloy technique by alternatively growing AlAs and InAs layers in the correct stoichiomety, the oxidation rate can be increased by several orders of magnitude, see B. Koley et al. “A method of incorporating wet-oxidized III-V semiconductor layers into indium phosphide based lasers and amplifiers,” Proc. IEEE 11^{th} Int. Conf. InP Rel. Mat., 20, 1999.

The confinement layer of the invention may be formed by a digital alloy technique and then oxidation in the wet nitrogen environment. It has also been found that these oxides formed from digital alloys are more robust with respect to post-annealing processes, which is disclosed in the article, G. W. Pickerell et al. “Improvement of wet-oxidized AlGaAs through the use of AlAs/GaAs digital alloys,” Appl. Phys. Lett., vol 76, p2544, 2000.

While the present invention has been described with reference to specific embodiments, the description is illustrative of the invention and is not to be construed as limiting the invention. Various modification may occur to those skilled in the art without departing from the true spirit and scope of the invention as defined by the appended claims.

What is claimed is:

1. A laser device comprising (a) an active region, and (b) a confinement region, the confinement region for confining carriers to the active region, wherein the confinement region comprises AlInAs doped with oxygen.

2. The laser device according to claim 1, wherein the confinement region further comprises aluminum oxide (Al₂O₃).

3. The laser device according to claim 2, wherein the aluminum oxide takes the form of an aluminum oxide (Al₂O₃) layer formed along the interface between the confinement region and its neighboring components including the active region.

4. The laser device according to claim 1, wherein the laser device includes an InP-based device.

5. The laser device according to claim 4, wherein the confinement region comprises a lattice-matched Al_{0.48}In_{0.52}As doped with oxygen.

6. The laser device according to claim 4, wherein the confinement region further comprises aluminum oxide (Al₂O₃).

7. The laser device according to claim 6, wherein the aluminum oxide takes the form of an aluminum oxide (Al₂O₃) layer formed along the interface between the confinement and its neighboring components including the active region.

8. The laser device according to claim 1, wherein the confinement region is formed by using a digital alloy technique.

9. The laser device according to claim 2, wherein the confinement region is formed by using a digital alloy technique and then applying a heat-treatment in wet nitrogen environment.

10. The laser device according to claim 4, wherein the confinement region is formed by using a digital alloy technique.

11. The laser device according to claim 7, wherein the aluminum oxide (Al₂O₃) layer is formed by heat-treating in wet nitrogen environment.

12. The laser device according to claim 6, wherein the confinement region is formed by using a digital alloy technique and then applying a heat-treatment in wet nitrogen environment.

13. An electrical confining member for use in a semiconductor device, the electrical confining member comprising AlInAs doped with oxygen.

14. An electrical confining member according to claim 13, wherein the AlInAs further comprises aluminum oxide (Al₂O₃).

15. An electrical confining member according to claim 13, wherein the aluminum oxide is the form of a layer which is formed along an interface between the electrical confining means and other components of the semiconductor device

16. An electrical confining member according to claim 13, wherein the semiconductor device includes an InP-based device.

17. An electrical confining member according to claim 16, wherein the AlInAs doped with oxygen comprises a lattice-matched Al_{0.48}In_{0.52}As doped with oxygen.

18. An electrical confining member according to claim 17, wherein the AlInAs doped with oxygen further comprises aluminum oxide (Al₂O₃).

19. An electrical confining member according to claim 18, wherein the aluminum oxide is the form of a layer which is formed along an interface between the electrical confining means and other components of the semiconductor device.

20. An electrical confining member according to claim 13, wherein the semiconductor device includes a laser device.

21. An electrical confining member according to claim 20, wherein the laser device includes an InP-based device.

22. An electrical confining member according to claim 21, wherein the AlInAs doped with oxygen comprises a lattice-matched Al_{0.48}In_{0.52}As doped with oxygen.

23. An electrical confining member according to claim 22, wherein the AlInAs doped with oxygen further comprises aluminum oxide (Al₂O₃).

24. An electrical confining member according to claim 23, wherein the aluminum oxide is the form of a layer which is formed along an interface between the electrical confining means and other components of the semiconductor device.
